(19) United States
(12) Patent Application Publication
(10) Pub. No.: US 2010/0151259 A1
(43) Pub. Date: Jun. 17, 2010

(54) AMORPHOUS METAL FILM AND PROCESS FOR APPLYING SAME

(76) Inventor: John C. Bilello, Ann Arbor, MI (US)

Correspondence Address: Waters & Associates, 161 Ottawa Ave., N.W., 305B WATERS BUILDING, Grand Rapids, MI, 49503, US

(21) Appl. No.: 12/066,133

(22) PCT Filed: Sep. 8, 2006
(86) PCT No.: PCT/US06/35113

§ 371 Date: Mar. 7, 2008

Related U.S. Application Data
(60) Provisional application No. 60/715,318, filed on Sep. 8, 2005.

(51) Int. Cl. B32B 15/04; C23C 14/34

(52) U.S. Cl. 428/457; 204/192.15

(57) ABSTRACT

Ni-based refractory metallic glass coatings utilizing periodic table group five element vanadium in combination with other group 5 or 6 elements, particularly tantalum, chromium, or molybdenum, can be formed via co-sputtering with proper control of carrier gas pressure and/or bias voltage. The alloy forms fully amorphous coatings that are not predicted by the usual glass forming ability (GFA) criteria. These alloys exhibit high thermal stability, hardness values greater than TiN, smooth surface finishes, and a wide processing window.

### CROSS-REFERENCE TO RELATED APPLICATIONS

This application is based in part on and claims the benefit of the filing date of Applicant's U.S. Provisional Application No. 60/715,318, filed Sep. 8, 2005, the disclosure of which is incorporated by reference.

### BACKGROUND OF THE INVENTION

The invention relates to amorphous metallic alloys and to a method of applying a protective coating of an amorphous metallic alloy of the invention.

Metallic alloys, under normal processing conditions, solidify as crystalline materials. Crystalline microstructures are characterized by long-range periodic arrangements of their atomic structure. Crystalline microstructures usually include a host of defects such as, dislocations and grain boundaries. These defects limit the strength, formability, and corrosion behavior (among other things) of conventional metallic alloys. Amorphous, or glass-like, materials have no long-range periodic structure and hence no dislocations or grain boundaries which limit the properties of conventional crystalline materials. Duwez and co-workers, starting in the late 1950's, performed pioneering work to create fully amorphous metallic materials. A summary of this early work can be found in “P. Duwez,” Trans. ASM, 60, (1967), 607.

Unfortunately, these early efforts to produce fully amorphous metallic alloys required extremely high cooling rates of the order of 10⁶° C./sec, which severely limited their range of applicability. Following on the work of Duwez it was shown by Turnbull and co-workers that certain exotic ternary metallic alloys such as Pd—Cu—Si could be cast in ordinary molds as amorphous materials with much lower cooling rates of the order of only a few ° C./sec. These discoveries created a lot of interest among materials scientists to be able to specify the exact conditions whereby a metallic alloy would solidify into a fully amorphous material. In a classical review article by Turnbull (see D. Turnbull, Contemp. Phys. 10, (1969), 473) he speculated that a wide range of alloy systems may be capable of forming metallic glasses of superior properties, but he could not provide a simple set of criteria for defining alloy systems that might work.

In the last 15 years a great deal of interest has focused on metallic glass formers, and researchers such as Johnson (see W. L. Johnson, Materials Science Forum, 225-227, (1996), 35) and Inoue (see A. Inoue and A. Takeuchi, Mater. Sci. & Eng. A, 375-377, (2004), 16) and co-workers have sought to define a concept called glass-forming ability (GFA) as a means for predicting alloys that are potentially capable of forming stable amorphous structures under conditions of minimal cooling rates usually associated with casting. Inoue has presented a simple set of rules for predicting GFA, which are as follows: “(1) being multicomponent consisting of more than three elements; (2) having a significant atomic size mismatches above 12% among the main three constituent elements; and (3) having a suitable negative heats of mixing among the main elements” (see A. Inoue, Non-Equilibrium Processing of Materials, Pergamon Press, (1999), 375, and see A. Inoue, Acta Meter, 48, (2000), 279). In Table 1 of Inoue's work, Non-Equilibrium Processing of Materials, he summarizes a large number of the known glass forming alloys. The only nickel-based systems mentioned in the group are: Ni—Zr—Ti—Sn—Si, Ni—(Nb,Ta)—Zr—Ti, and Ni—Si—B—Ta. All these fit within the realm of the three criteria stated for suitable GFA.

Recently, Johnson and co-workers have found that a series of nickel-based ternary and quaternary alloys of the form Ni—Nb—Sn and Ni—Nb—Sn—X (where X=B, Fe, Cu) are good glass formers (see H. Choi-Yim, D. Xu and W. L. Johnson, Applied Phys. Lett., 82, (2003), 1030). The stability of this class of amorphous materials has been shown to be marginal, however. Nickel-based alloys of this former class were shown to devitrify (i.e. crystallize) when heated for only 90 minutes at 460° C., which was well below the glass transition temperature of 600° C. for these materials (see M. L. Tokarz, Structure and Stability of Ni-Based Refractory Amorphous Metal Alloys, Ph. D. Thesis, University of Michigan, 2004).

It is important to note that if a presumed metallic glass alloy is partially crystalline the crystallites can serve as nuclei for devitrification at temperatures well below the glass transition temperature. This devitrification will cause a severe diminution in the physical properties of said alloy leading to deleterious effects in service. Ordinary laboratory x-ray sources are insufficient to detect nanocrystalline residuals that may be left as a result of any processing procedure used to form metallic glass. Recent results have shown that one must employ low divergence synchrotron scattering observations, which has 50 times better resolution for detecting nanocrystalline residuals than that possible with usual laboratory XRD methods (see M. L. Tokarz and J. C. Bilello, MRS Symp. Proceedings, 754, (2004), MM9.5).

Finally, it is known that metallic glasses can be processed by a variety of methods, provided the cooling rate is properly controlled. For purposes of producing thin films of alloys, DC magnetron sputtering is capable of the type of control required for producing metallic glass coatings.

### BRIEF SUMMARY OF THE INVENTION

In accordance with the present invention, an article of manufacture comprises a substrate material coated with an amorphous metal film, wherein the metal film comprises an alloy including nickel and vanadium in combination with tantalum, chromium, or molybdenum or other of at least the non rare earth elements in groups 5 and 6 of the periodic table, in proportions and conditions sufficient to produce an amorphous material when applied in a thin film to the substrate.

The film desirably is applied by co-sputtering. Co-sputtering is preferred over the use of a monolithic, preformed alloy. Preformed alloys having the desired composition are difficult to form, whereas the relative proportions of the elements can be controlled carefully and adjusted as necessary employing a co-sputtering process. In addition, the use of a monolithic alloy having a given composition may not result in a coating having the same composition, due to the different properties of the alloy components.

The proportion of vanadium in the composition is at least about 3% and may be as much as 10% or more. Preferably, vanadium is present in the amount of about 4-7%.

These and other features and properties of the present invention are described in detail below and illustrated in the appended drawings.

### BRIEF DESCRIPTION OF THE SEVERAL VIEWS OF THE DRAWING

FIG. 1 is a graph showing the result of a high-resolution synchrotron x-ray scan on a 1 μm thick Ni—Ta—V fully amorphous metallic glass film of nominal composition: 66.48 wt. % tantalum and 29.43wt. % nickel (sample LAZ_{—}019);

FIG. 2 is a series of graphs showing the synchrotron high-resolution diffraction patterns for a series of fully amorphous Ni—Ta—V metallic glass alloy coatings taken over a composition range varying from (A) 54 at. % Ni, 40 at. % Ta, 7 at. % V; to (B) 57 at. % Ni, 37 at. % Ta, 6 at. % V; to (C) 67 at. % Ni, 26 at. % Ta, 7 at. % V.

FIG. 3 is a graph showing the narrow processing window for Ni—Nb—Sn alloys. Only the Rag 3 Ni—Nb—Sn alloy composition produced a fully amorphous alloy without any residual polycrystalline diffraction peaks superimposed on the broad amorphous maxima;

FIG. 4 is a graph showing a high-resolution synchrotron diffraction pattern taken on a 3 μm thick Ni₅₄Ta₄₀V₆. The coating is fully amorphous with no indication of nanocrystalline residuals;

FIG. 5 is a graph showing a high-resolution synchrotron diffraction taken on after thermal stability run;

FIG. 6 is a table showing hardness of nickel coatings compared to amorphous Ni—Ta—V alloys; and

FIG. 7 is a graph showing a comparison of observations on the same sample for data taken with a conventional Laboratory XRD source and with that taken on beamline 2-1 at the Stanford Synchrotron Radiation Laboratory, with some of the crystalline diffraction lines being indicated with arrows.

FIGS. 8A and 8B are phase diagrams for nickel and chromium and nickel and molybdenum, respectively.

FIG. 9 is a chart reflecting nano-indentation data for Ni—V—Mo and Ni—V—Cr.

FIGS. 10A and 10B are sample plots of nano-indentation data for Ni—V—Mo.

FIGS. 11A and 11B are sample plots of nano-indentation data for Ni—V—Cr.

FIGS. 12A and 12B are synchrotron scattering data for a one micron layer of Ni—V—Cr.

FIGS. 13A and 13B are charts reflecting thermal stability data for a one micron coating of Ni—V—Cr, reflecting control samples and samples after eighteen hours at 350 C, respectively.

FIGS. 14A and 14B are charts reflecting thermal stability data for a one micron coating of Ni—V—Mo, reflecting control samples and samples after eighteen hours at 350 C, respectively.

### DETAILED DESCRIPTION OF THE INVENTION

The attached drawings illustrate data for several embodiments of the present invention, wherein stable amorphous metal films are produced by co-sputtering nickel and vanadium, along with other of at least the non rare earth elements in Groups 5 and 6 of the periodic table. Specific examples of compositions including tantalum, chromium, and molybdenum are shown. From this it is concluded that all of at least the non rare earth elements in Groups 5 and 6, including niobium and tungsten as well as the foregoing, will produce desirable amorphous metal films.

One preferred embodiment of an amorphous metal film according to the invention is a nickel-vanadium-tantalum alloy. Nickel-tantalum (Ni—Ta) forms a deep eutectic where the slope of the liquidus is about 45.6° C./wt. % Ta. Under equilibrium cooling conditions nickel crystallizes as a face centered cubic metal and tantalum as a body centered cubic polycrystal. This alloy system can be made into a fully amorphous coating by physical vapor deposition via DC magnetron sputtering without following Inoue's rules for GFA by using vanadium (V) as a third alloy addition.

According to published empirical data on atomic radii, tantalum has an atomic radius of 145 pm, nickel of 135 pm and vanadium of 135 pm, respectively (see: www.webelements.com). Thus, nickel and vanadium are almost identical in atomic radius and they differ only by 7% from tantalum, while Inoue's criteria call for atomic radius greater than 12%. Furthermore, the alloy additions (beyond the initial binary) used to form metallic glasses have usually been chosen from the group III, IV or V columns of the periodic table (see A. Inoue and A. Takeuchi, Mater. Sci. & Eng. A, 375-377, (2004), 16). The present invention does not require either the size variation or the requirement of using a metalloid element, which makes for far easier processing in making alloy targets and in subsequent control of the processing parameters.

In addition, the eledronic structure of vanadium alloy additions added to a nickel target in an amount of 1-2% is known to defeat the usual magnetic field difficulties that would occur in sputtering from a pure nickel target. More importantly, in this case, the more substantial (at least about 3% and preferably 4% or more) vanadium additions to the resulting Ni—Ta alloy film help frustrate the diffusion of Ni—Ta and prevent normal crystallization processes from occurring. Control of the processing conditions via the carrier gas pressure range or bias voltage, individually or together, is set so that the arrival energies of the sputtered atomic species are limited to a few eV/atom, which further limits Ni—Ni, Ta—Ta and Ta—Ni associations that could lead to crystallization.

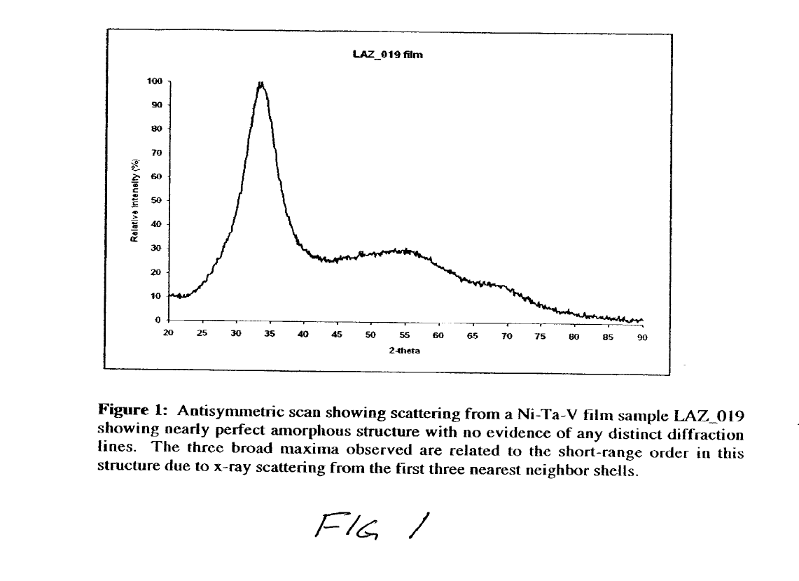

The results of this processing and alloy control are shown in FIG. 1, which shows the result of a high-resolution synchrotron x-ray scan on a 1 μm thick Ni—Ta—V fully amorphous metallic glass film of nominal composition: 66.48 wt. % tantalum, 29.43 wt. % nickel, and 4.09% vanadium (sample LAZ_{—}019). Under the conditions that this x-ray data was taken on high-resolution x-ray scattering beamline 2-1 this material is fully amorphous (it will be shown in the examples that the criteria for being fully amorphous is not necessarily met by ordinary laboratory XRD observations).

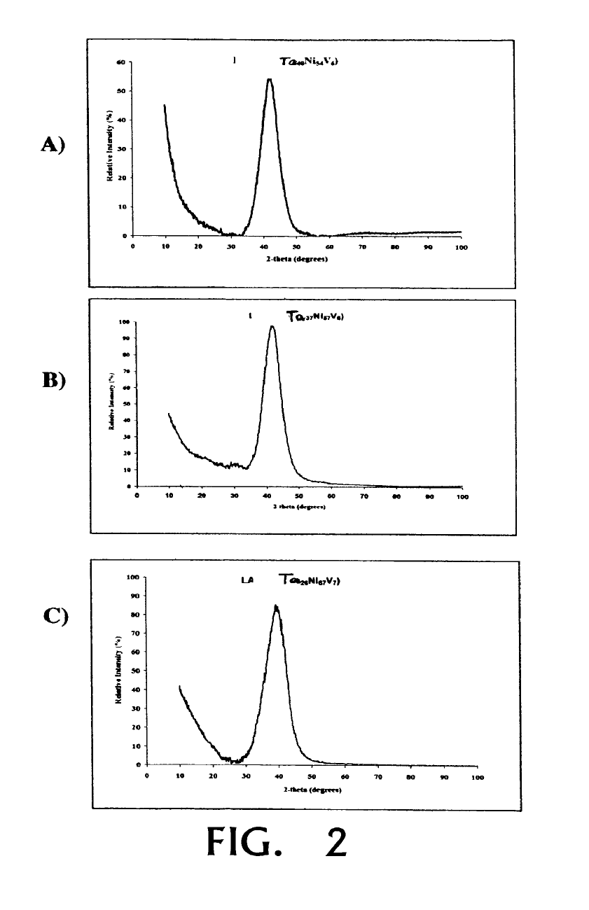

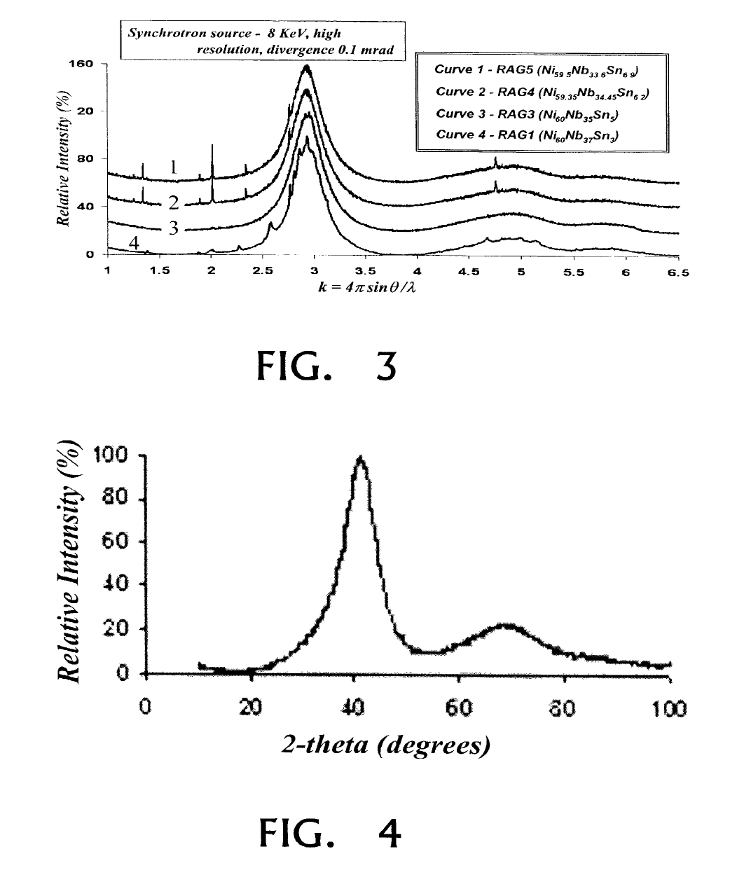

The processing window for the Ni—Ta—V alloy is robust, with nickel compositions from 54 at. %/Ni to 67 at. % Ni all producing fully amorphous films. This is demonstrated in FIG. 2, which shows the synchrotron high-resolution diffraction patterns for a series of metallic glass alloys taken over this composition range. In contrast to an alloy of the Ni—Nb—Sn system, which does follow the Inoue GAF criteria, it can be shown to exhibit crystalline diffraction peaks (FIG. 3) when the processing window is varied as little as about ±1.2 at. % Sn from the ideal composition for the fully amorphous condition.

The Ni—Ta—V metallic glass coatings have a reasonable thickness range over which they still remain fully amorphous. While FIG. 1 shows the result for a 1 μm thick coating, FIG. 4 shows the result of a high-synchrotron diffraction pattern for a 3 μm thick film. The greater heating that accompanies thicker coatings had no apparent effect on this refractory Ni—Ta—V and fully amorphous films resulted.

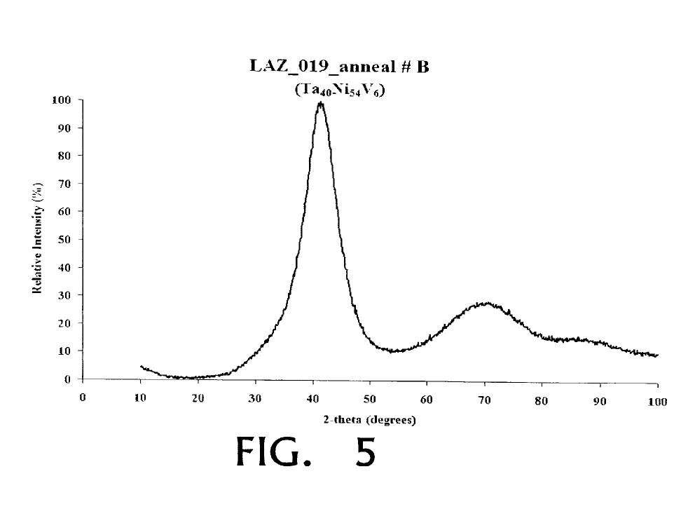

The Ni—Ta—V amorphous coatings are also extremely resistant to devitrification. A 1 μm thick coating of the LAZ_{—}019 Ni—Ta—V film was heated for 18 hours of annealing at 500° C. (932° F.) in an Ar environment, (i.e. sealed in a quartz capsule which was evacuated and backfilled with slight positive pressure of Ar gas at 1.1 atm). The results of high-resolution x-ray scattering observations on samples subjected to this annealing treatment are shown in FIG. 5. Diffraction patterns were taken at a number of positions on the surface of that this film was coated upon and all were found to be fully amorphous.

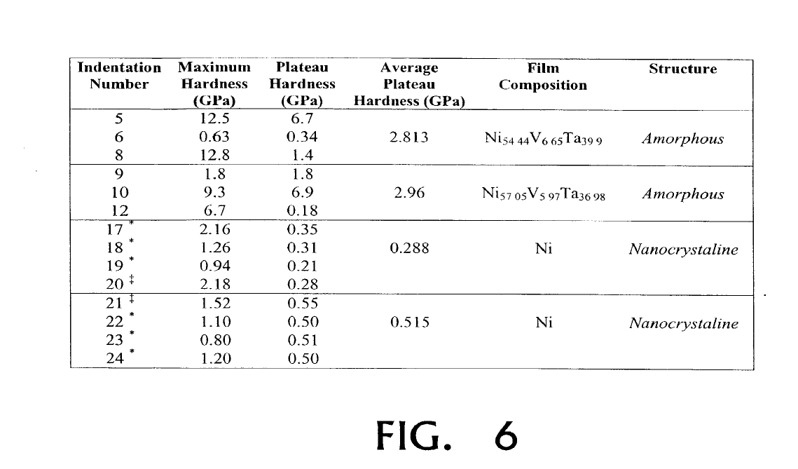

The strength of these films was measured by nanoindentation and found to be superior to nickel metallic coatings. The lack of the usual dislocation defects found in conventional alloying methods for these metallic constituents made these films exceptionally hard. The data in FIG. 6 compares results taken on our Ni—Ta—V fully amorphous films with similar observations taken on nickel polycrystalline coatings of comparable thickness. These results indicate that the hardness of Ni—Ta—V fully amorphous metallic glass coatings can be as much 10 times (2.96/0.288) harder than conventional polycrystalline nickel coatings. Hardness measurements were on conventional TiN decorative coatings and the Ni—Ta—V films outperform this material also. The average value of the hardness of the TiN coatings was 0.43 GPa compared to 2.89 GPa for the Ni—Ta—V fully amorphous metallic glass coatings.

### EXAMPLES

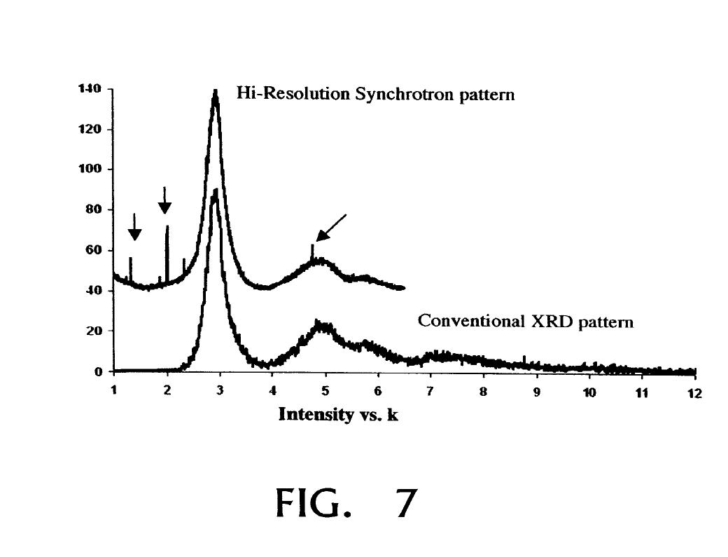

(1) The conventional method for assessing the amorphous nature of a solid material is to do a conventional laboratory x-ray diffraction pattern (XRD). The problem with this in working with metallic glass coating is two-fold. First the scattering intensity from thin film is generally very low because of the restricted scattering volume and hence it is difficult to get good counting statistics. It is also hard to separate out scattering from the underlying substrate. The usual divergence of the best Laboratory x-ray machines is about 5 mrad, while that for beamline 2-1 at Stanford Synchrotron Radiation Laboratory is 0.1 mrad (a 50:1 improvement). That means that conventional XRD would have great difficulty in telling the difference between a nanocrystalline material (which would still have and enormous number of defects, especially considering the grain boundary area) and a full amorphous material. A comparison between conventional XRD and a high-resolution synchrotron diffraction pattern taken on the same exact sample for the same incident beam illuminated area is shown in FIG. 7. The sharp diffraction peaks in the Synchrotron pattern show that this material is not a fully amorphous metallic glass. All data in this application claiming fully amorphous structures has been verified using high-resolution synchrotron radiation observations.

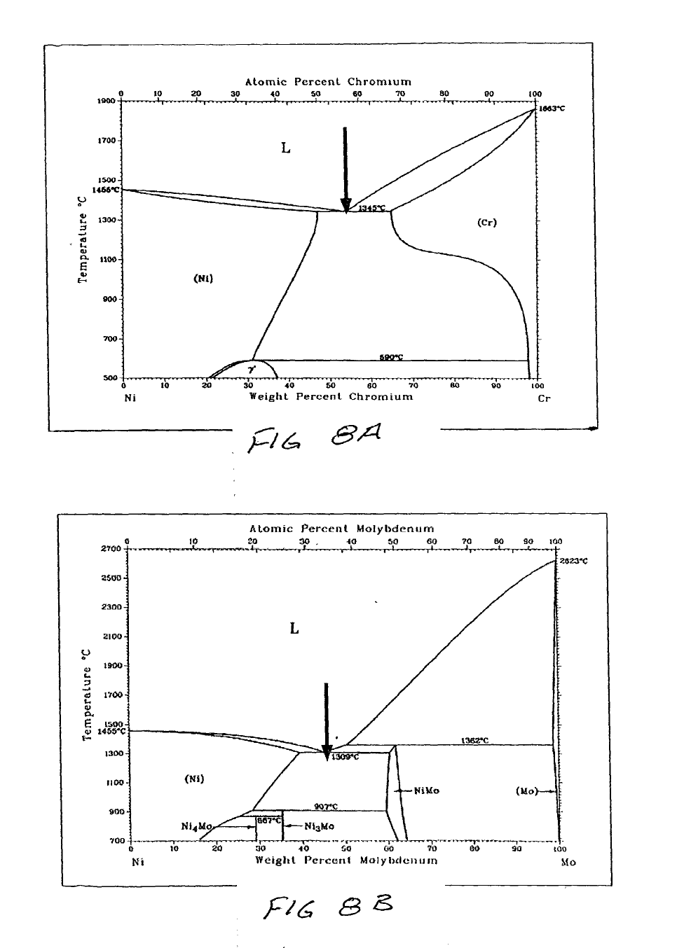

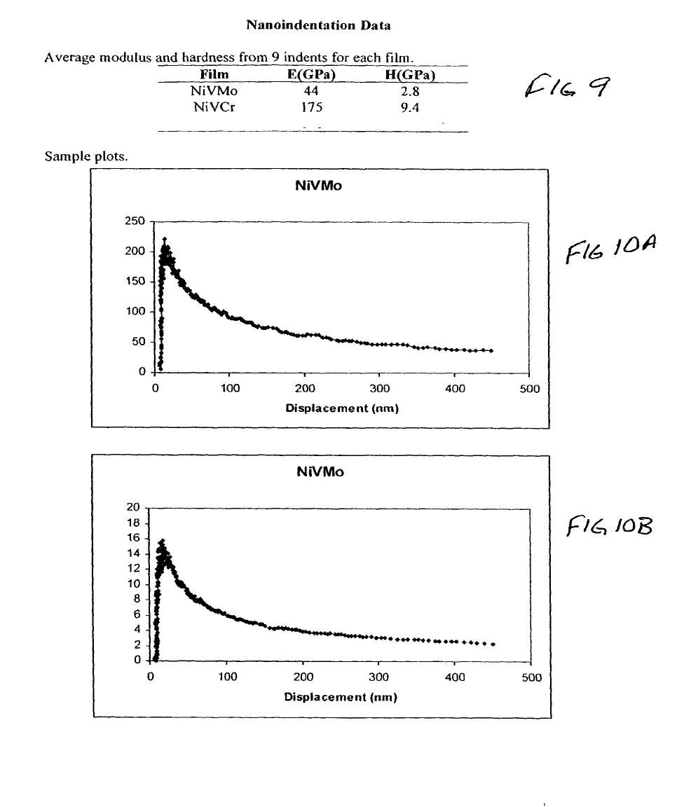

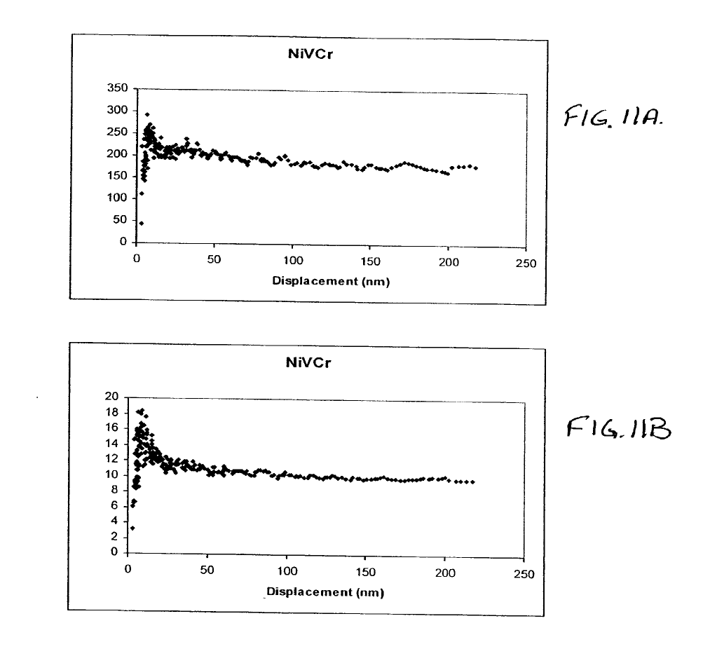

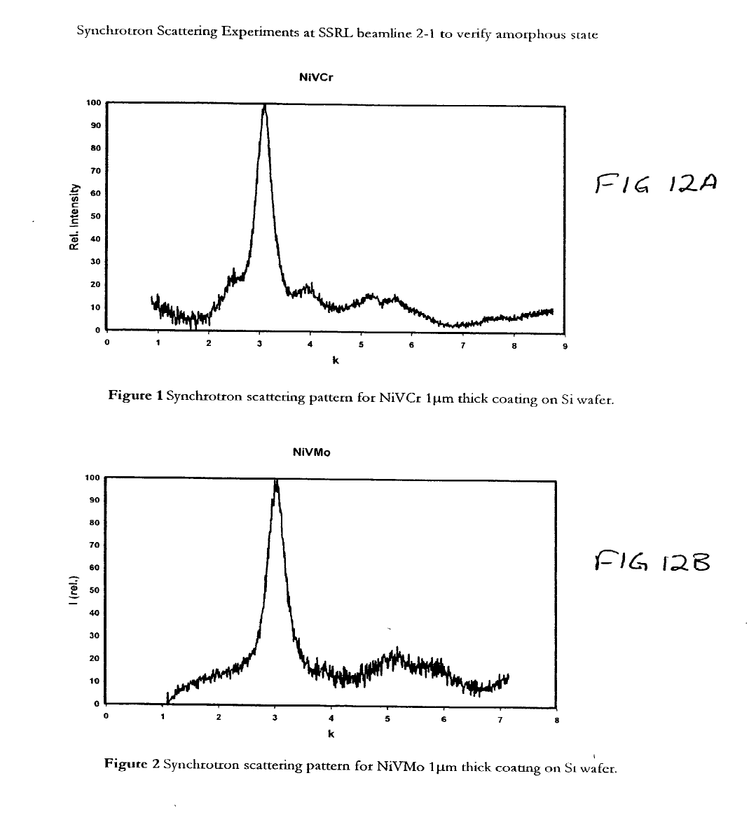

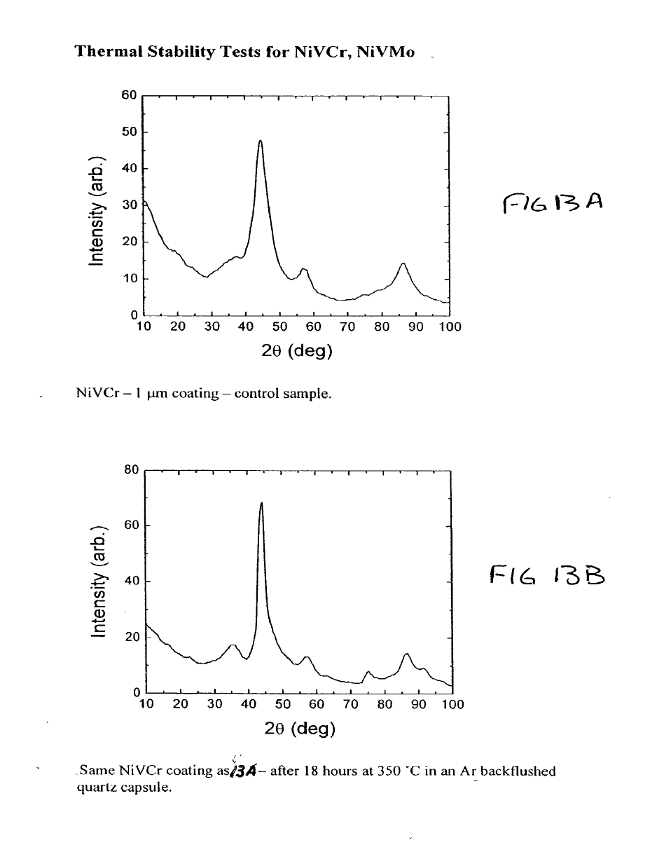

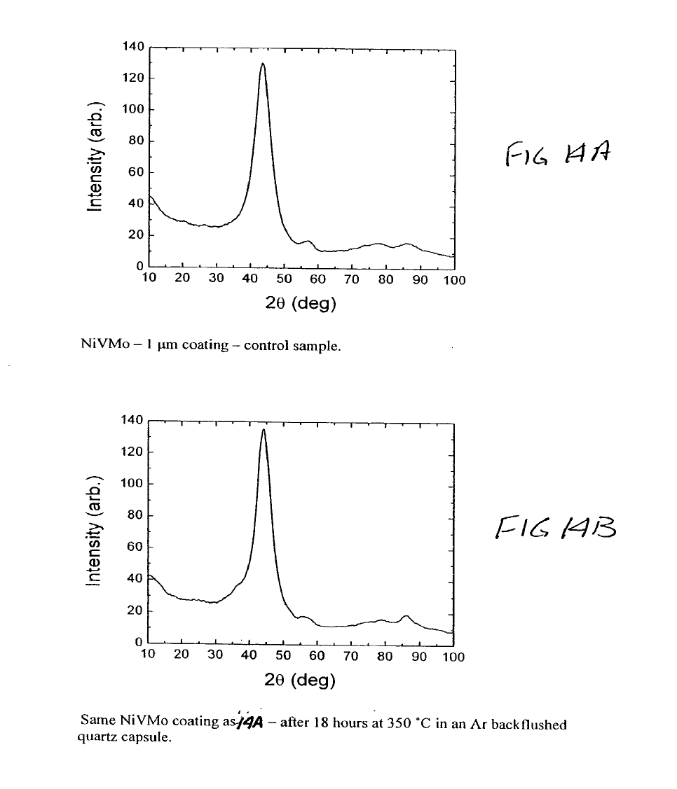

In addition to tantalum, it has been found that other group 5 and group 6 elements may be combined with nickel and vanadium in order to produce stable amorphous films having desirable characteristics. FIGS. 8-14 comprise phase diagrams, hardness data, and charts, synchrotron scattering experiments, and thermal stability tests that demonstrate that periodic table group 6 elements chromium and molybdenum, when combined with nickel and vanadium produce thermally stable amorphous films having improved physical characteristics, as well as Ni—V compositions including tantalum. The proportions of the elements and the procedures for forming the films are analogous to the proportions and procedures employed for tantalum films, described above.

The foregoing evaluations of Ni—V compositions employing group 5 and 6 elements Ta, Cr, and Mo support the proposition that compositions including the other non-rare earth elements in groups 5 and 6, niobium or tungsten, in combination with Ni—V also will produce stable amorphous films.

The films of the present invention are particularly advantageous when they are applied to a suitable substrate by a physical vapor deposition (PVD) process, such as D.C. magnetron sputtering. With some prior alloy compositions and application methods (e.g. molten metal applications), very precise composition ranges were necessary to produce an amorphous product or coating. To achieve these tolerances, it was necessary to employ pre-formulated alloys, which are very expensive, and to control cooling rates. In the present invention, the component composition ranges can vary significantly, so the components do not have to be applied as a preformulated alloy, but can be applied separately (co-sputtered) as separate targets. This is substantially more cost effective. In addition, the use of PVD techniques appears to make it possible to form amorphous coatings with a wider variation in component proportions.

While each of the components can be applied as a separate target, it can be desirable and does not involve significant extra expense to employ the nickel and vanadium as a target and to co-sputter the composition along with tantalum.

Also, the application by PVD techniques such as D.C. magnetron sputtering, does not involve melting the film components and therefore controlled cooling rates are not a factor.

In addition to the foregoing advantages, the use of a PVD process for applying the amorphous film of the present invention to a substrate provides a desirably thin film coating, which is cost effective, while at the same time providing a coating having improved physical characteristics that adheres well to the substrate. When used for a decorative and protective coating, for example, the coatings of the present invention provide surface finishes that are attractive, extremely durable and scratch resistant, and cost effective.

The films of the present invention can be applied in varying thicknesses. Decorative films on articles can be as thin as about 0.2 microns. When the film is as thin as 0.1 micron, the film becomes substantially transparent and therefore provides a more limited decorative function. A typical decorative finish might be about 0.25 microns to one micron thick. Substantially thicker coatings are feasible. Machine elements that are coated for hardness or low friction characteristics might employ an amorphous coating 4-10 microns thick.

One having ordinary skill in the art and those who practice the invention will understand from this disclosure that various modifications and improvements may be made without departing from the spirit of the disclosed inventive concept.

What is claimed is:

1. An article of manufacture comprising a substrate material coated with an amorphous metal film comprising an alloy including nickel and vanadium in combination with at least one of tantalum, chromium, molybdenum, tungsten and niobium, in proportions and conditions sufficient to produce an amorphous material when applied in a thin film to the substrate.

2. An article of manufacture as in claim 1 wherein the coating is applied by physical vapor deposition.

3. An article of manufacture as in claim 1 wherein the coating is applied by sputtering.

4. An article of manufacture as in claim 1 wherein the coating components comprise nickel, tantalum, and vanadium in the following proportions:
54 to 67 at. wt % Ni
40 to 26 at. wt % Ta
4 to 7 at. wt % V.

5. An article of manufacture as in claim 1 wherein the alloy is comprised substantially of nickel, tantalum and vanadium in the following approximate proportions:
54 to 67 at. wt % Ni
40 to 26 at. wt % Ta
6 to 7 at. wt % V.

6. An article of manufacture as in claim 1 wherein the coating is no greater than about 10 microns thick.

7. An article of manufacture as in claim 6 wherein the coating is no more than about 3 microns thick.

8. An article of manufacture as in claim 7 wherein the coating is no more than about 2 microns thick.

9. An article of manufacture as in claim 8 wherein the coating is no more than about 1 microns thick.

10. An article of manufacture as in claim 9 wherein the coating is about 0.2 to about 1 micron thick.

11. An article of manufacture as in claim 10 wherein the alloy coating is formed in situ by co-sputtering one or more components separately.

12. An article of manufacture wherein a Ni—V alloy is co-sputtered with one of Ta, Cr and Mo to form an amorphous surface film on a substrate.

13. A method for producing an article having a decorative or protective surface coating comprising applying to a substrate a metallic film comprising nickel, vanadium, and one or more of tantalum, chromium, molybdenum, tungsten, and niobium in proportions and under conditions such that the metallic film forms an amorphous film on the substrate.

14. A method as in claim 13 wherein the film is applied by physical vapor deposition.

15. A method as in claim 13 wherein the film is applied by sputtering.

16. A method as in claim 13 wherein the film is applied by D.C. magnetron sputtering.

17. A method as in claim 13 wherein the film is applied by co-sputtering at least some of the alloy components.

18. A method as in claim 13 wherein the film is applied by co-sputtering a Ni—V alloy and Ta, Cr, or Mo as separate targets.

19. A method as in claim 13 wherein the coating is applied in a thickness of up to about 10 microns.

20. A method as in claim 13 wherein the coating is applied in a thickness of up to about one (1) micron.
